(19) United States
(12) Patent Application Publication
(10) Pub. No.: US 2011/0039390 A1
(43) Pub. Date: Feb. 17, 2011

(54) Reducing Local Mismatch of Devices Using Cryo-Implantation

(75) Inventors: Chun-Feng Nieh, Hsin-Chu (TW); Chun Hsiung Tsai, Hsin-Chu (TW); Yuan-Hung Chiu, Taipei (TW); Hun-Jan Tao, Hsin-Chu (TW)

Correspondence Address: SLATER & MATSIL, L.L.P., 17950 PRESTON ROAD, SUITE 1000, DALLAS, TX, 75252, US

(73) Assignee: Taiwan Semiconductor Manufacturing Company, Ltd., Hsin-Chu (TW)

(21) Appl. No.: 12/784,348

(22) Filed: May 20, 2010

Related U.S. Application Data
(60) Provisional application No. 61/234,015, filed on Aug. 14, 2009.

(51) Int. Cl. H01L 21/336

(52) U.S. Cl. 438/305; 257/E21.437

(57) ABSTRACT

A method of forming an integrated circuit includes providing a semiconductor wafer, and forming a metal-oxide-semiconductor (MOS) device. The step of forming the MOS device includes forming a gate stack on the semiconductor wafer, and performing a cryo-implantation to form an implantation region adjacent the gate stack at a wafer temperature lower than 0° C. The step of performing the cryo-implantation is selected from the group consisting essentially of implanting the semiconductor wafer to form a pre-amorphized implantation (PAI) region; implanting the semiconductor wafer to form a lightly-doped source/drain region; implanting the semiconductor wafer to form a pocket/halo region; implanting the semiconductor wafer to form a deep source/drain region, and combinations thereof

This application claims the benefit of U.S. Provisional Application No. 61/234,015 filed on Aug. 14, 2009, entitled “Reducing Local Mismatch of Devices Using Cryo-Implantation,” which application is hereby incorporated herein by reference.

### TECHNICAL FIELD

This invention relates generally to integrated circuit devices and more particularly to methods for manufacturing integrated circuit devices.

### BACKGROUND

Integrated circuits are manufactured on wafers. Typically, each wafer includes a plurality of chips, wherein the chips are typically identical to each other. To reduce the manufacturing costs, the wafers become increasingly larger. Currently, wafers having 12-inch diameters are manufactured. With larger wafers, more chips can be manufactured simultaneously.

To ensure the quality of the integrated circuits, it is desirable that the devices on different chips, but at the same relative locations of the respective chips, are identical to each other and have the exact same performance. However, each device in a wafer has its own local environment, which may be different from the environment of other corresponding devices. For example, the devices close to the edges of wafers may have different environments than the devices close to the center of the respective wafers. Different environments result in the local mismatch in the performance of the devices.

In addition, it is desirable that even in a same chip, the devices of a same type have the same performance, so that the performance of the integrated circuit is more predictable. However, local mismatch also affects the performance uniformity of these devices. What is needed, therefore, is an integrated circuit manufacturing method for overcoming the above-described shortcomings in the prior art.

### SUMMARY OF THE INVENTION

In accordance with one aspect of the embodiment, a method of forming an integrated circuit includes providing a semiconductor wafer, and forming a metal-oxide-semiconductor (MOS) device. The step of forming the MOS device includes forming a gate stack on the semiconductor wafer, and performing a cryo-implantation to form an implantation region adjacent the gate stack at a wafer temperature lower than 0° C. The step of performing the cryo-implantation is selected from the group consisting essentially of implanting the semiconductor wafer to form a pre-amorphized implantation (PAI) region; implanting the semiconductor wafer to form a lightly-doped source/drain region; implanting the semiconductor wafer to form a pocket/halo region; implanting the semiconductor wafer to form a deep source/drain region, and combinations thereof

Other embodiments are also disclosed.

The advantageous features of the embodiments include reduced random impurity fluctuation in implanted regions of integrated circuit devices, reduced leakage currents, and increased activation rate of impurities in the implanted regions.

### BRIEF DESCRIPTION OF THE DRAWINGS

For a more complete understanding of the present invention, and the advantages thereof, reference is now made to the following descriptions taken in conjunction with the accompanying drawings, in which:

FIGS. 1 through 3 are cross-sectional views of intermediate stages in the manufacturing of an MOS device in accordance with an embodiment;

FIGS. 4 and 5 illustrate implanters for performing cryo-implantations; and

FIGS. 6-8 are experiment results illustrating the effect of cryo-implantations.

### DETAILED DESCRIPTION OF ILLUSTRATIVE EMBODIMENTS

The making and using of the embodiments of the present invention are discussed in detail below. It should be appreciated, however, that the embodiments provide many applicable inventive concepts that can be embodied in a wide variety of specific contexts. The specific embodiments discussed are merely illustrative of specific ways to make and use the invention and do not limit the scope of the invention.

A novel method for forming integrated circuits is provided. The intermediate stages of manufacturing an embodiment are illustrated. The variations of the embodiment are then discussed. Throughout the various views and illustrative embodiments, like reference numbers are used to designate like elements.

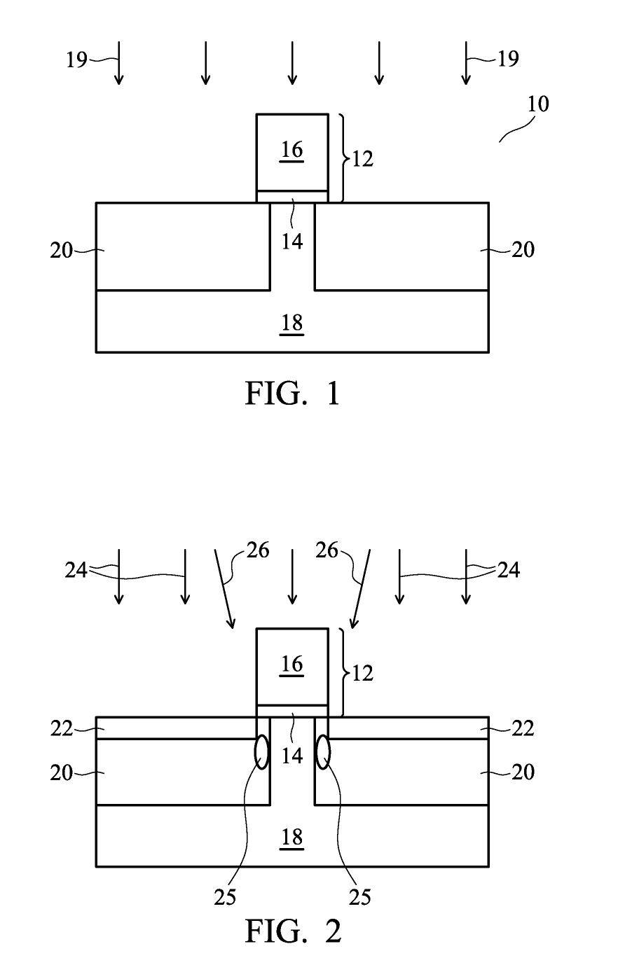

FIGS. 1 through 3 illustrate cross-sectional views of intermediate stages in the manufacturing of a metal-oxide-semiconductor (MOS) device. Referring to FIG. 1, wafer 10 is provided. Wafer 10 may include a plurality of chips, which will have circuits formed thereon. The circuits on each of the chips will be identical to the circuits on other chips. Wafer 10 further includes semiconductor substrate 18, which may be formed of commonly known semiconductor materials, such as silicon, silicon germanium, gallium arsenide, and the like. Gate stack 12, which includes gate dielectric 14 and gate electrode 16, is formed on substrate 18.

In an embodiment, a pre-amorphized implantation (PAI), as symbolized by arrows 19, is performed. During the PAI, portions of semiconductor substrate 18 are amorphized, and hence PAI regions 20 are formed. In an embodiment, the PAI is performed by implanting silicon, germanium, and/or carbon into semiconductor substrate 18. In other embodiments, inert gases, such as neon, argon, krypton, xenon, and/or radon may be implanted. The PAI has two functions. First, vacancies are created in the lattice structure of semiconductor substrate 18, so that the subsequently implanted p-type or n-type impurities may occupy the vacancies. Accordingly, the activation rate may be improved. Second, in the amorphized semiconductor substrate 18, atoms are arranged randomly and hence the subsequently implanted p-type or n-type impurities cannot channel through the spaces between the periodically located atoms to reach an undesirably great depth.

Next, as shown in FIG. 2, lightly-doped source/drain (LDD) regions 22, also commonly known as source/drain extension (SDE) regions 22, is formed. In an embodiment, the desirable type of the resulting MOS device is n-type. Accordingly, n-type impurities, such as phosphorous, arsenic, antimony, and combinations thereof, may be implanted. Conversely, if the desirable type of the resulting MOS device is p-type, then p-type impurities, such as boron, indium, and combinations thereof, may be implanted. The implantation is symbolized by arrows 24, which implantation may be vertical.

Further, pocket/halo regions 25 are also formed by an implantation(s), as symbolized by arrows 26. Pocket/halo regions 25 have a conductivity type opposite to the conductivity type of LDD regions 22. Implantation 26 may be performed with a tilt, so that pocket/halo regions 25 may extend under gate stack 12.

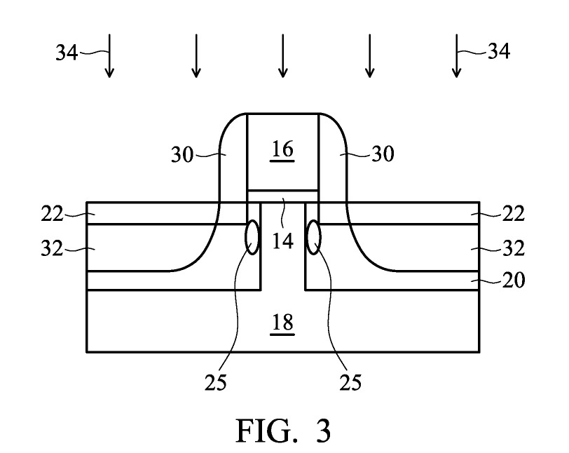

FIG. 3 illustrates the formation of gate spacers 30 and source/drain regions 32, which are also sometimes referred to as deep source/drain regions 32. Source/drain regions 32 may be formed, for example, after the formation of gate spacers 30 and performed through a further implantation, as symbolized by arrows 34. Again, if an n-type MOS device is desirable, then n-type impurities, such as phosphorous, arsenic, antimony, and combinations thereof, may be implanted. Conversely, if the desirable type of the resulting MOS device is p-type, then p-type impurities, such as boron, indium, and combinations thereof, may be implanted.

In an embodiment, one or more of implantations 19, 24, 26, and 34, as shown in FIGS. 1 through 3, may use cryo-implantation in any combination. In alternative embodiments, all of implantations 19, 24, 26, and 34, as shown in FIGS. 1 through 3, may be performed using cryo-implantations. In a cryo-implantation, wafer 10 is first cooled to a temperature lower than about 0° C. before the corresponding implantation starts. The temperature of wafer 10 may also be lower than about −30° C., −60° C., −90° C., or may even be close to −196° C., which is the temperature of liquid nitrogen. During the implantation, wafer 10 is kept at the low temperature. Further, some, but not all, of the implantations 19, 24, 26, and 34 may be performed at room temperature, which may be about 20° C. to about 25° C., and the room-temperature implantation may be combined with the cryo-implantation to form the MOS devices. For example, some of the implantations 19, 24, 26, and 34 may be cryo-implantations, while the remaining ones of implantations 19, 24, 26, and 34 may be room-temperature implantations.

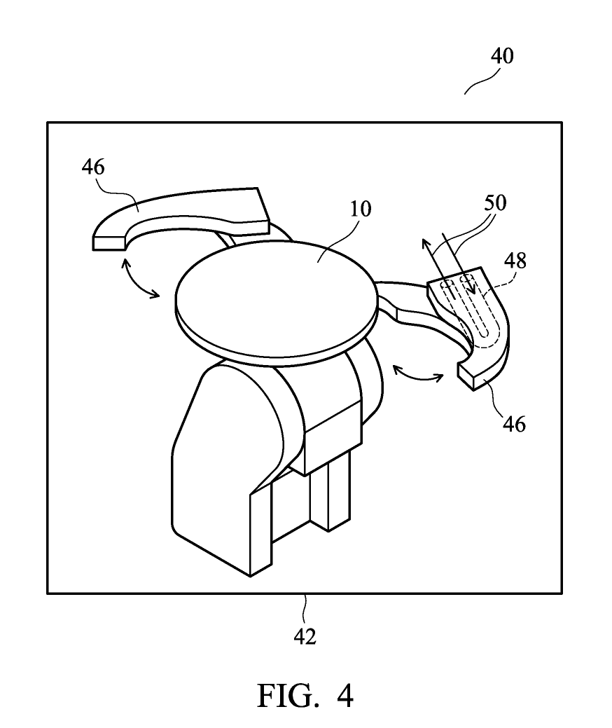

FIG. 4 illustrates portions of exemplary implanter 40 for performing the cryo-implantation. Implanter 40 may include chamber 42, which may be vacuumed. Wafer 10 is placed in chamber 42. Cold pads 46 are placed close to wafer 10. Cold pads 46 are capable of being cooled to a desirable low temperature, for example, lower than about −30° C., −60° C., −90° C., or even close to −196° C. In an embodiment, each of cold pads 46 has an internal pipeline 48. When liquid and/or gaseous coolant, such as nitrogen, flows through internal pipeline 48, cold pads 46 are cooled. Arrows 50 illustrate the flow of the coolant. Internal pipeline 48 may be connected to a Dewar bottle (not shown), in which liquid nitrogen or helium is stored.

Referring again to FIG. 4, before one of implantations 19, 24, 26, and 34 (FIGS. 1 through 3) starts, cold pads 46 may clamp on the edge and/or the bottom surface of wafer 10. Since silicon is a good thermal conductor, wafer 10 is also cooled to the desirable temperature through the contact with cold pads 46. The cryo-implantation may then be performed. In an embodiment, the cryo-implantation is performed after the cold pads 46 are moved away from wafer 10. In alternative embodiments, the cryo-implantation is performed when cold pads 46 are still in contact with wafer 10. In an exemplary embodiment, nitrogen (symbolized by arrows 50) is introduced into internal pipeline 48 to cool cold pads 46. The state of nitrogen is determined based on the desirable temperature of wafer 10, and may be at the liquid state, the gaseous state, or a state with mixed liquid and gas. In an exemplary embodiment, a desirable wafer temperature for performing the cryo-implantation is −60° C. Accordingly, gaseous nitrogen that is evaporated from the liquid nitrogen may be used and may have a flow rate of about 5 sccm to about 30 sccm.

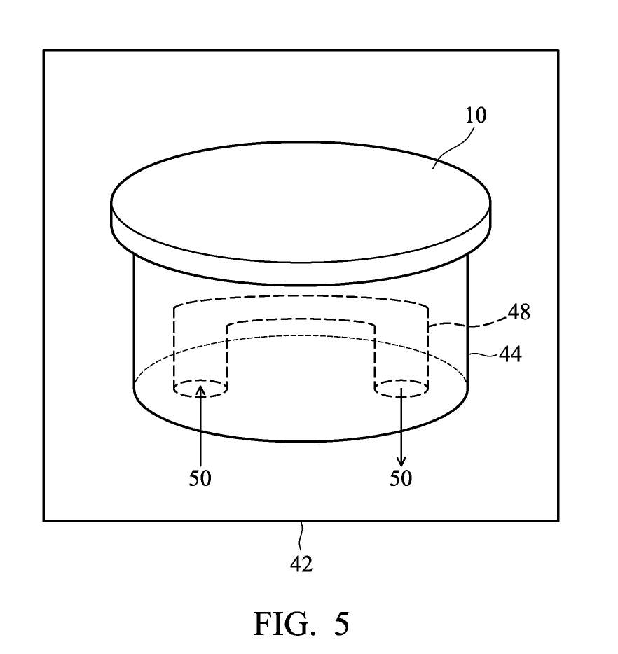

FIG. 5 illustrates an alternative embodiment. In this embodiment, instead of using cold pads 46, electrical chuck (E-Chuck) 44, on which wafer 10 is secured, acts as the cooling medium. In this embodiment, internal pipeline 48 may be built in E-Chuck 44 and used to conduct liquid/gaseous coolant 50, such as liquid/gaseous nitrogen, helium, or the like. Since wafer 10 is secured on E-Chuck 44, E-Chuck 44 will cool wafer 10 to desirable temperatures. In this embodiment, during the cryo-implantations, wafer 10 may be continuously cooled.

The embodiments of the present invention have several advantageous features. With the cryo-implantations, the random impurity fluctuation in the implanted regions of integrated circuit devices is reduced. The depths of the implanted regions in different portions of wafers are more uniform, and the interface between implanted and un-implanted regions becomes smoother. The cryo-implantations result in more point defects rather than cluster defects. As a result, in the activation of the implanted regions, more implanted ions can be activated, resulting in lower sheet resistances. Further, leakage currents may be reduced. Experiments have revealed that using a cryo-implantation rather than performing an implantation at room temperature, the leakage current density of the respective MOS device may be reduced from 0.0029 nA/μm to 0.0016 nA/μm.

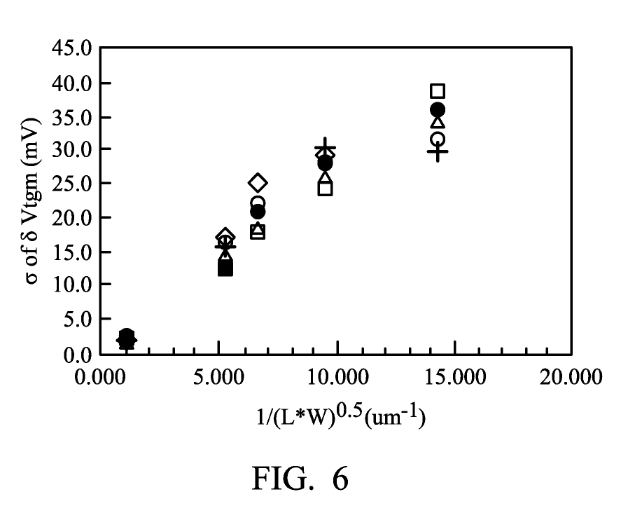

FIGS. 6-8 illustrate some experiment results. Referring to FIG. 6, the average local mismatch in threshold voltage (σ of δ Vtgm, Y-axis) in wafers is illustrated as a function of the dimension of MOS devices, wherein L is the channel length and W is the channel width of the MOS devices. The squares are obtained from samples made using implantations performed at room temperature, while all other results illustrated using other shapes are obtained from samples made using cryo-implantations. It is noted that with the increase of X-axis values (hence the reduction in the size of MOS devices), the local mismatch in threshold voltages all increase. However, if the results represented by different shapes are fitted using fit lines, the fit lines of cryo-implantation results rise slower than the fit line of the room-temperature results (squares) with the increase in X-axis values, indicating that with the reduction of the sizes of the MOS devices, the Vt mismatches of the devices formed using the cryo-implantations increase slower than that of the devices formed using the room-temperature implantations. Further, at the benchmark value wherein the X-axis value equals 15.000, the cryo-implantations already result in a smaller mismatch in threshold voltage Vt than the room-temperature implantations.

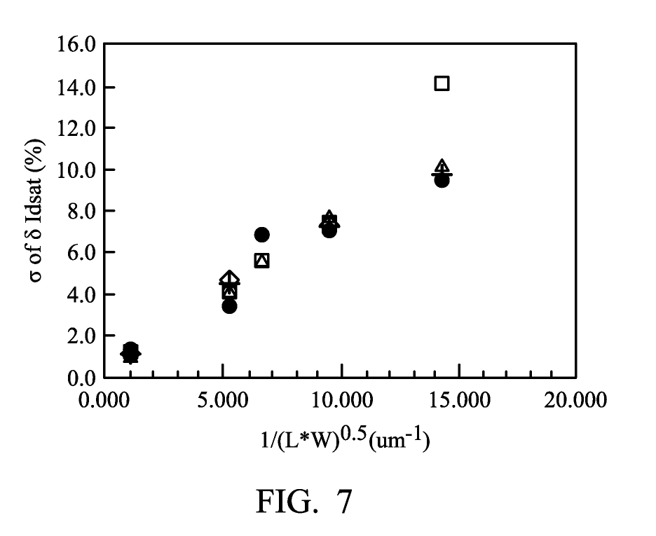

FIG. 7 illustrates the average local mismatch in saturation current (σ of δ Idsat) on wafers as a function of the dimension of MOS devices. Similar conclusions may be drawn that with the reduction in size of the MOS devices, the Idsat mismatch of the devices formed using the cryo-implantations increase slower, and eventually becomes smaller than that of the devices formed using the room-temperature implantations. At the benchmark value wherein the X-axis value equals 15.000, the cryo-implantations already result in smaller mismatch in Idsat than the room-temperature implantations.

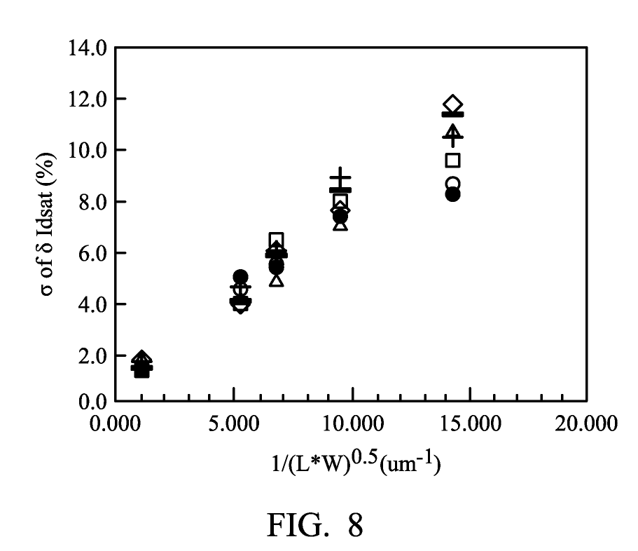

The results shown in FIGS. 6 and 7 are obtained from PMOS devices. FIG. 8 illustrates results obtained from NMOS devices. Please note that in FIG. 8, the diamond with the highest Y-axis value is obtained from samples made using implantations performed at room temperature, while all other results having other shapes are obtained from samples made using cryo-implantations. It is observed that the PMOS devices and NMOS devices have the same tendency of having smaller local mismatch if formed using cryo-implantations than formed using room-temperature implantations. It is further noted that when the X-axis value equals 15.000, the cryo-implantations already result in a smaller mismatch in Idsat than the room-temperature implantations, with an improvement as great as 4 percent (12 percent minus 8 percent).

Although the present invention and its advantages have been described in detail, it should be understood that various changes, substitutions and alterations can be made herein without departing from the spirit and scope of the invention as defined by the appended claims. Moreover, the scope of the present application is not intended to be limited to the particular embodiments of the process, machine, manufacture, and composition of matter, means, methods and steps described in the specification. As one of ordinary skill in the art will readily appreciate from the disclosure of the present invention, processes, machines, manufacture, compositions of matter, means, methods, or steps, presently existing or later to be developed, that perform substantially the same function or achieve substantially the same result as the corresponding embodiments described herein may be utilized according to the present invention. Accordingly, the appended claims are intended to include within their scope such processes, machines, manufacture, compositions of matter, means, methods, or steps. In addition, each claim constitutes a separate embodiment, and the combination of various claims and embodiments are within the scope of the invention.

What is claimed is:

1. A method of forming an integrated circuit, the method comprising:
providing a semiconductor wafer; and
implanting the semiconductor wafer using a cryo-implantation to form an implanted region.

2. The method of claim 1, wherein the cryo-implantation comprises cooling a temperature of the semiconductor wafer to lower than about −30° C.

3. The method of claim 1, wherein the cryo-implantation comprises cooling a temperature of the semiconductor wafer to lower than about −60° C.

4. The method of claim 1 further comprising, before the step of implanting the semiconductor wafer, cooling a cold pad, and contacting the cold pad with the semiconductor wafer.

5. The method of claim 4, wherein the step of cooling the cold pad is performed using liquid nitrogen.

6. The method of claim 1 further comprising, before the step of implanting the semiconductor wafer, cooling a electrical chuck, wherein the semiconductor wafer is secured on the electrical chuck.

7. The method of claim 1, wherein the implanted region is a pre-amorphized implantation (PAI) region adjacent a gate stack of a metal-oxide-semiconductor (MOS) device, and wherein the method further comprises, after the step of implanting the semiconductor wafer to form the PAI region, performing an additional implantation step to form a source/drain region.

8. The method of claim 1, wherein the implanted region is a lightly doped source/drain region of a MOS device.

9. The method of claim 1, wherein the implanted region is a pocket/halo region of a MOS device.

10. The method of claim 1, wherein the implanted region is a deep source/drain region of a MOS device.

11. A method of forming an integrated circuit, the method comprising:
providing a semiconductor wafer; and
forming a metal-oxide-semiconductor (MOS) device comprising:
forming a gate stack on the semiconductor wafer;
performing a cryo-implantation to form an implantation region adjacent the gate stack at a wafer temperature lower than 0° C., wherein the step of performing the cryo-implantation is selected from the group consisting essentially of:
implanting the semiconductor wafer to form a pre-amorphized implantation (PAI) region;
implanting the semiconductor wafer to form a lightly-doped source/drain region;
implanting the semiconductor wafer to form a pocket/halo region; and
implanting the semiconductor wafer to form a deep source/drain region.

12. The method of claim 11, wherein the cryo-implantation comprises the step of implanting the semiconductor wafer to form the deep source/drain region.

13. The method of claim 11, wherein the cryo-implantation comprises the step of implanting the semiconductor wafer to form the lightly-doped source/drain region.

14. The method of claim 11, wherein the cryo-implantation comprises the step of implanting the semiconductor wafer to form the PAI region.

15. The method of claim 11, wherein the cryo-implantation comprises the step of implanting the semiconductor wafer to form the PAI region, the step of implanting the semiconductor wafer to form the lightly-doped source/drain region, and the step of implanting the semiconductor wafer to form the deep source/drain region.

16. The method of claim 11, wherein the wafer temperature is lower than about −30° C.

17. The method of claim 11, wherein the wafer temperature is lower than about −60° C.

18. The method of claim 11 further comprising:
before the step of performing the cryo-implantation, introducing a nitrogen-containing coolant to cool a cold pad; and
contacting the cold pad with an edge of the semiconductor wafer.

19. The method of claim 11 further comprising:
before the step of performing the cryo-implantation, introducing a nitrogen-containing coolant to cool a cold pad; and
contacting the cold pad with a backside of the semiconductor wafer.

20. The method of claim 11 further comprising, during the step of performing the cryo-implantation, introducing a nitrogen-containing coolant to cool an electrical chuck, wherein the semiconductor wafer is secured on the electrical chuck.
